(19) United States
(12) Patent Application Publication
(10) Pub. No.: US 2013/0057084 A1
(43) Pub. Date: Mar. 7, 2013

(54) HALL PLATE SWITCHING SYSTEM

(71) Applicant: Soo Woong LEE, Gyeonggi-Do (KR)

(72) Inventor: Soo Woong LEE, Gyeonggi-Do (KR)

(73) Assignee: SAMSUNG ELECTRO-MECHANICS CO., LTD., Suwon (KR)

(21) Appl. No.: 13/602,447

(22) Filed: Sep. 4, 2012

(30) Foreign Application Priority Data
Sep. 5, 2011 (KR) 10-2011-0089706

(51) Int. Cl. H03K 17/90

(52) U.S. Cl. 307/113

(57) ABSTRACT

Disclosed herein is a hall plate switching system including: a hall plate that generates first hall voltage at both ends of a first node and a third node facing each other and generates second hall voltage at both ends of a second node and a fourth node facing each other; a first switch unit that is connected with the first node and the second node and controls on/off of current flowing in the first node and the second node; a second switch unit that is connected with the third node and the fourth node and controls on/off of current flowing in the third node and the fourth node; and a resistor unit that is connected with the second switch unit and reduces trans-conductance of the first switch unit and the second switch unit.

### CROSS REFERENCE(S) TO RELATED APPLICATIONS

This application claims the benefit under 35 U.S.C. Section 119 of Korean Patent Application Serial No. 10-2011-0089706, entitled “Hall Plate Switching System” filed on Sep. 5, 2011, which is hereby incorporated by reference in its entirety into this application.

### BACKGROUND OF THE INVENTION

1. Technical Field

The present invention relates to a hall plate switching system, and more particularly, to a hall plate switching system capable of compensating for a mismatch occurring at a hall plate of a magnetic sensor.

2. Description of the Related Art

A magnetic sensor used for various applications such as a speed sensor, a position sensor, a current sensor, and the like, is a system for outputting hall voltage according to magnetic field intensity by a Lorenz's law. That is, when magnetic field and current are present, the hall voltage is output in proportion to the current intensity.

As a structure of the system for outputting hall voltage by sensing the magnetic field, a magnetic field sensitive MOSFET (MAGFET) and a hall plate structure have been mainly used, wherein the MAGFET is a structure of splitting a drain node of a field effect transistor (FET) to convert magnetic field into voltage.

In a method for removing offset voltage by a hall plate structure according to the related art, magnitudes in each resistance of a Wheat-stone bridge type are substantially different due to process variation and therefore, a part of the offset voltage remains. In this case, parasitic resistance occurs at each node, such that the offset voltage of the hall plate resistor and the parasitic resistance occurring at each node of the hall plate become factors of degrading accuracy of the hall voltage.

In order to overcome the foregoing problems of the related art, there is a need to optimize the effect of the parasitic resistance and the noise level of the system that occur due to the process variation, when considering the use of a weak signal. That is, there is a need to compensate for the offset voltage due to the parasitic resistance occurring during the process of the hall plate.

### SUMMARY OF THE INVENTION

An object of the present invention is to reduce offset voltage due to parasitic resistance occurring at a hall pate of a magnetic sensor, that is, compensate for a mismatch.

According to an exemplary embodiment of the present invention, there is provided a hall plate switching system, including: a hall plate that generates first hall voltage at both ends of a first node and a third node facing each other and generates second hall voltage at both ends of a second node and a fourth node facing each other; a first switch unit that is connected with the first node and the second node and controls on/off of current flowing in the first node and the second node; a second switch unit that is connected with the third node and the fourth node and controls on/off of current flowing in the third node and the fourth node; and a resistor unit that is connected with the second switch unit and reduces trans-conductance of the first switch unit and the second switch unit.

The hall plate switching system may further include: a switching control unit that is connected with the first switch unit and the second switch unit and performs a control to simultaneously switch the first switch unit and the second switch unit.

The first switch unit may include a first node switch connected with the first node and a second node switch connected with the second node, and the second switch unit may include a third node switch connected with the third node and a fourth node switch connected with the fourth node.

The second node switch may operate a clock at a phase difference of 180° from the first node switch and the fourth node switch may operate a clock at a phase difference of 180° from the third node switch.

The second node switch and the third node switch may operate clocks without the phase difference.

The first node switch to the fourth node switch may be a metal oxide semiconductor field effect transistor (MOSFET).

The resistor may include: a first resistor that is connected with the third node switch and reduces the trans-conductance of the second node switch and the third node switch; and a second resistor that is connected with the fourth node switch and reduces the trans-conductance of the first node switch and the fourth node switch.

The first resistor and the second resistor may have different values.

The hall plate switching system may further include: a current source that is connected with the resistor unit to reduce a mismatch of a differential pair.

### BRIEF DESCRIPTION OF THE DRAWINGS

FIG. 1 is a perspective view of a structure of a hall plate.

FIG. 2 is a circuit diagram showing an operating principle of outputting hall voltage according to the structure of the hall plate and a magnetic field direction.

FIGS. 3 and 4 are circuit diagrams showing a spinning current method according to the related art for compensating for an offset of hall plate resistance.

FIG. 5 is a diagram showing a hall plate switching system for compensating for an offset of hall plate resistance according to an exemplary embodiment of the present invention.

FIG. 6 is a diagram showing a hall plate switching system for compensating for an offset of hall plate resistance according to another exemplary embodiment of the present invention.

### DESCRIPTION OF THE PREFERRED EMBODIMENTS

Hereinafter, exemplary embodiments of the present invention will be described in detail with reference to the accompanying drawings. However, this is only by way of example and therefore, the present invention is not limited thereto.

When technical configurations known in the related art are considered to make the contents obscure in the present invention, the detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

Hereinafter, the exemplary embodiments of the present invention will be described with reference to the accompanying drawings.

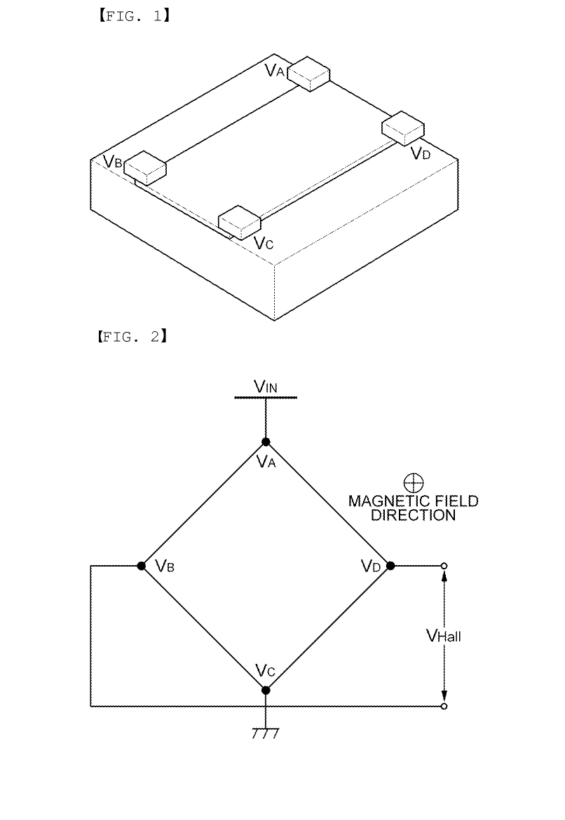

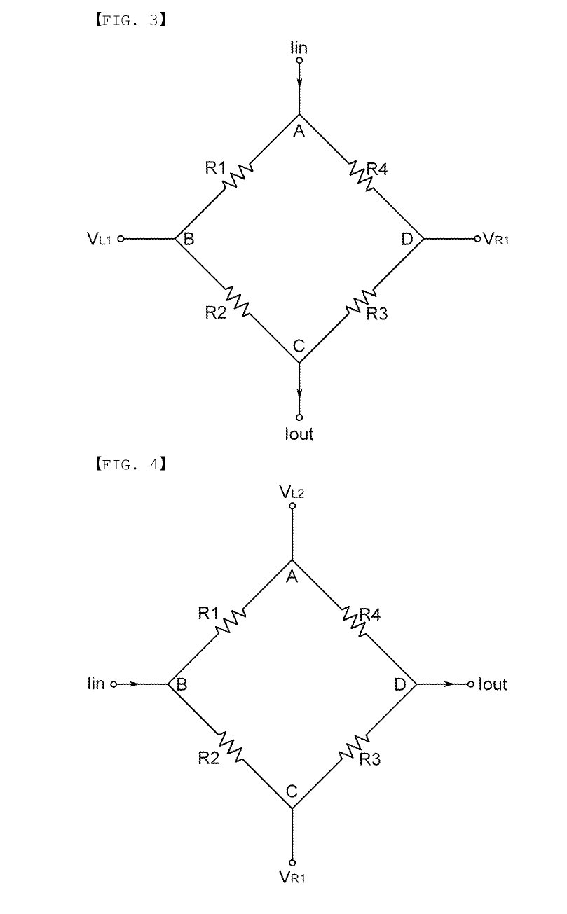

FIG. 1 is a perspective view of a structure of a hall plate and FIG. 2 is a circuit diagram showing an operating principle of outputting hall voltage according to the structure of the hall plate and a magnetic field direction.

The hall plate has a structure of implementing a specific resistance value within a P-substrate. When considering a commercial value, and the like, the hall plate shows excellent characteristics, and therefore, most of the magnetic sensors have adopted the structure of the hall plate.

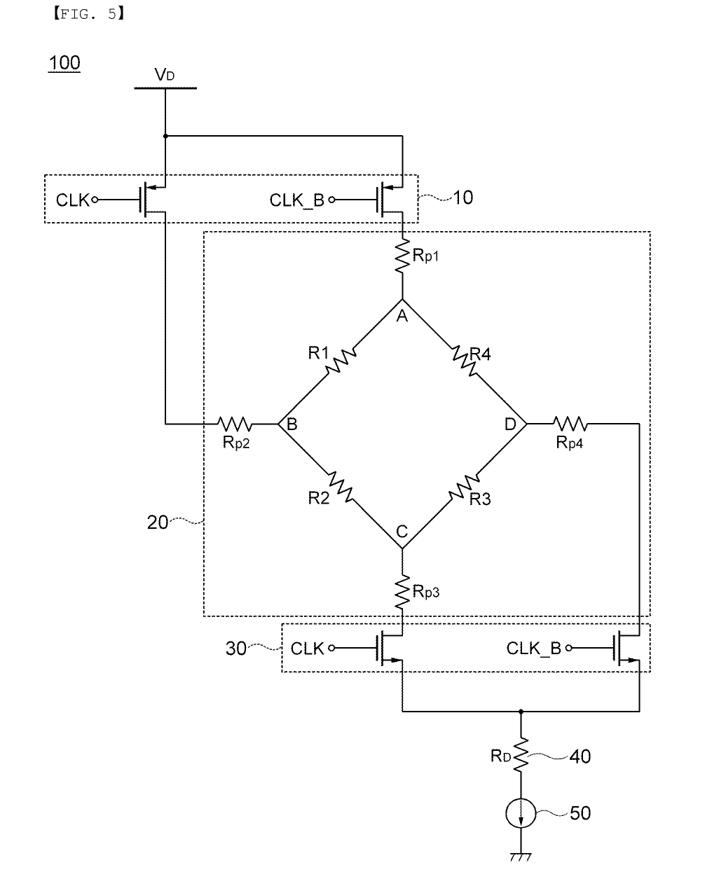

FIGS. 3 and 4 are circuit diagrams showing a spinning current method for compensating for offset voltage of hall plate resistance.

$$\begin{matrix}{V}_{off \_ 1} = {V}_{1.1} - {V}_{R 1} = ( \frac{R 2}{R 1 + R 2} - \frac{R 3}{R 3 + R 4} ) \cdot {V}_{IN} & [ Equation 1 ] \\ {V}_{off \_ 2} = {V}_{1.2} - {V}_{R2} = ( \frac{R 1}{R 1 + R 4} - \frac{R4}{R 2 + R3} ) \cdot {V}_{IN} & [ Equation 2 ] \\ {V}_{off \_ total} = {V}_{off \_ 1} + {V}_{off \_ 2} = ( \frac{R 2 \cdot R 4 - R 1 \cdot R 3}{( R 1 + R 2 ) \cdot ( R 3 + R 4 )} + \frac{R 1 \cdot R 3 - R 2 \cdot R 4}{( R 1 + R 4 ) \cdot ( R 2 + R 3 )} ) \cdot {V}_{IN} & [ Equation 3 ]\end{matrix}$$

Equations 1 and 2 each represent the offset voltage occurring due to a phase difference and Equation 3 is an Equation that represents a process of removing the offset voltage by the spinning current method. As can be appreciated from Equation 3, in case of R1=R3 and R2=R4, the overall offset voltage may be set to be 0.

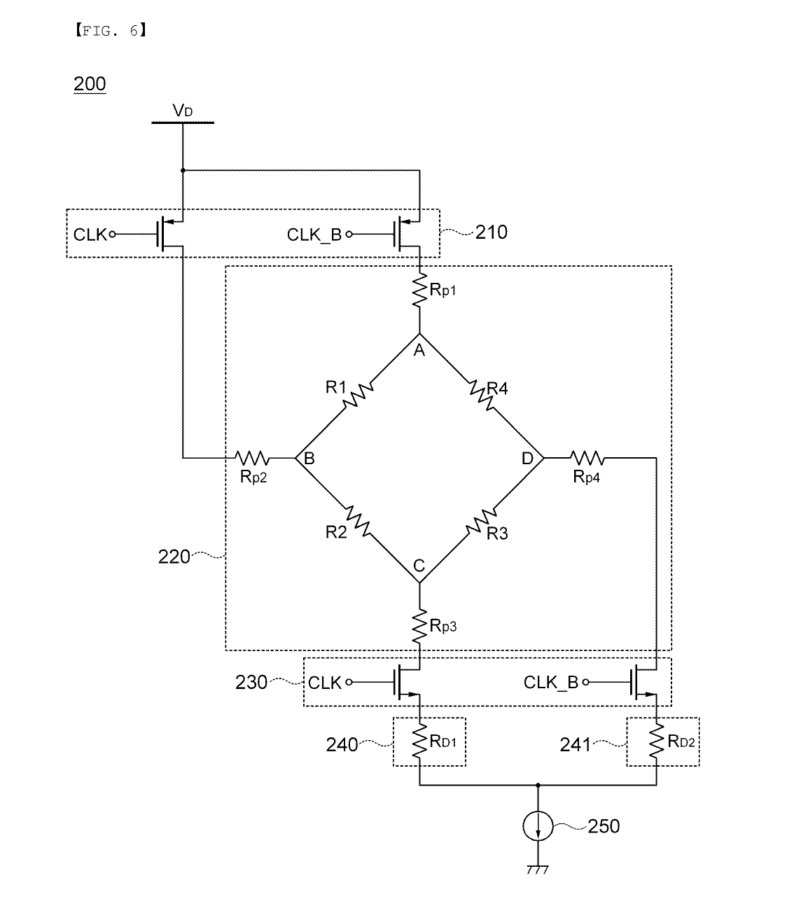

FIG. 5 is a diagram showing a hall plate switching system for compensating for an offset of hall plate resistance according to an exemplary embodiment of the present invention.

As shown in FIG. 5, a hall plate switching system 100 according to an exemplary embodiment of the present invention may include a hall plate 20 that generates first hall voltage at both ends of a first node A and a third node C facing each other and generates second hall voltage at both ends of a second node B and a fourth node D facing each other; a first switch unit 10 that is connected to the first node A and the second node B and controls on/off of current flowing in the first node A and the second node B; a second switch unit 30 that is connected to the third node C and the fourth node D and controls on/off of current flowing in the third node C and the fourth node D; and a resistor unit 40 that is connected to the second switch unit 30 and reduces trans-conductance of the first switch unit 10 and the second switch unit 30.

The hall plate 100 may be used for a magnetic sensor and may be mounted on a P-substrate of the magnetic sensor. In addition, the hall plate 100 may be equivalently analyzed to a wheat-stone bridge resistor circuit. When performing the analysis by the equivalent circuit, the hall plate 100 may generate the first hall voltage at both ends of the first node A and the third node C facing each other and the second hall voltage at both of the second node B and the fourth node D facing each other.

The first switch unit 10 may be connected with the first node A and the second node B and the second switch unit 30 may be connected with the third node C and the fourth node D. Therefore, the first switch unit 10 may control the on/off of current flowing in the first node A and the second node B and the second switch unit 30 may control the on/off of current flowing in the third node C and the fourth node D.

The resistor unit 40 may be connected with the second switch unit 30. Therefore, the resistor unit 40 may serve to reduce the trans-conductance of the first switch unit 10 and the second switch unit 30 and reduce a mismatch due to the parasitic resistance occurring at the hall plate of the related art.

In this case, the hall plate 100 may further include a current source 50 connected with the resistor unit 40 to reduce a mismatch of a differential pair.

The current source 50 may be connected between the resistor unit 40 and the second switch unit 30 and may also be connected between the resistor unit 40 and a ground. Therefore, the current source 50 may serve to reduce the mismatch of the differential pair occurring at a circuit having the differential structure and reduce the mismatch occurring at the hall plate of the related art.

In this case, the hall plate 100 may further include a switching control unit (not shown) that is connected with the first switch unit and the second switch unit 30 and performs a control to simultaneously switch the first switch unit 10 and the second switch unit 30.

Therefore, the first hall voltage may occur at both ends of the first node A and the third node C and the second hole voltage may occur at both ends of the second node B and the fourth node D. In this case, the first switch unit 10 may include a first node switch connected with the first node A and a second node switch connected with the second node B and the second switch unit 30 may include a third node switch connected with the third node C and a fourth node switch connected with the fourth node D.

In this case, the second node switch may operate a clock at a phase difference of 180° from the first node switch and the fourth node switch may operate a clock at a phase difference of 180° from the third node switch.

In this case, the second node switch and the third node switch may operate the clocks without the phase difference.

Meanwhile, the first node switch to the fourth node switch may be a metal oxide semiconductor field effect transistor (MOSFET). In this case, the first node switch and the second node switch may be a P-MOS and the third node switch and the fourth node switch may be an N-MOS.

FIG. 6 is a diagram showing a hall plate switching system for compensating for an offset of hall plate resistance according to another exemplary embodiment of the present invention.

As shown in FIG. 6, the resistor unit 40 may include a first resistor 240 that is connected with the third node switch and reduces the trans-conductance of the second node switch and the third node switch and a second resistor 241 that is connected with the fourth node switch and reduces the trans-conductance of the first node switch and the fourth node switch. Therefore, the first resistor 240 and the second resistor 241 may serve to reduce the trans-conductance of the first switch unit 210 and the second switch unit 230 and reduce the mismatch due to the parasitic resistance occurring at the hall plate of the related art.

In this case, the first resistor 240 and the second resistor 241 may have different values.

Meanwhile, the hall plate switching system may further include a current source 250 that is connected with the first resistor 240 and the second resistor 241 to reduce the mismatch of the differential pair. Therefore, the current source 250 may serve to reduce the mismatch of the differential pair occurring at a circuit having the differential structure and reduce the mismatch occurring at the hall plate of the related art.

According to the exemplary embodiments of the present invention, no distortion occurs at the output due to the effect of the mismatch compensation despite the parasitic resistance of the hall plate.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A hall plate switching system, comprising:
a hall plate that generates first hall voltage at both ends of a first node and a third node facing each other and generates second hall voltage at both ends of a second node and a fourth node facing each other;
a first switch unit that is connected with the first node and the second node and controls on/off of current flowing in the first node and the second node;
a second switch unit that is connected with the third node and the fourth node and controls on/off of current flowing in the third node and the fourth node; and
a resistor unit that is connected with the second switch unit and reduces trans-conductance of the first switch unit and the second switch unit.

2. The hall plate switching system according to claim 1, further comprising: a switching control unit that is connected with the first switch unit and the second switch unit and performs a control to simultaneously switch the first switch unit and the second switch unit.

3. The hall plate switching system according to claim 2, wherein the first switch unit includes a first node switch connected with the first node and a second node switch connected with the second node, and
the second switch unit includes a third node switch connected with the third node and a fourth node switch connected with the fourth node.

4. The hall plate switching system according to claim 3, wherein the second node switch operates a clock at a phase difference of 180° from the first node switch, and
the fourth node switch operates a clock at a phase difference of 180° from the third node switch.

5. The hall plate switching system according to claim 4, wherein the second node switch and the third node switch operate clocks without the phase difference.

6. The hall plate switching system according to claim 5, wherein the first node switch to the fourth node switch are a metal oxide semiconductor field effect transistor (MOSFET).

7. The hall plate switching system according to claim 6, wherein the resistor includes:
a first resistor that is connected with the third node switch and reduces the trans-conductance of the second node switch and the third node switch; and
a second resistor that is connected with the fourth node switch and reduces the trans-conductance of the first node switch and the fourth node switch.

8. The hall plate switching system according to claim 7, wherein the first resistor and the second resistor have different values.

9. The hall plate switching system according to claim 1, further comprising:
a current source that is connected with the resistor unit to reduce a mismatch of a differential pair.

10. The hall plate switching system according to claim 7, further comprising:
a current source that is connected with the resistor unit to reduce a mismatch of a differential pair.
